(19) United States
(12) Patent Application Publication
(10) Pub. No.: US 2017/0271622 A1
(43) Pub. Date: Sep. 21, 2017

(54) HIGH EFFICIENCY THIN FILM TANDEM SOLAR CELLS AND OTHER SEMICONDUCTOR DEVICES

(71) Applicant: Ashok Chaudhari, Briarcliff Manor, NY (US)

(72) Inventor: Ashok Chaudhari, Briarcliff Manor, NY (US)

(73) Assignee: Solar-Tectic, LLC, Briarcliff Manor, NY (US)

(21) Appl. No.: 15/611,343

(22) Filed: Jun. 1, 2017

Related U.S. Application Data
(60) Provisional application No. 62/345,406, filed on Jun. 3, 2016.

(51) Int. Cl. H01L 51/52; H01L 31/0236; H01L 31/0216; H01L 29/786; H01L 31/0304; H01L 31/0224; H01L 31/0749; H01L 31/0725; H01L 31/0352

(52) U.S. Cl. CPC H01L 51/5268; H01L 31/0725; H01L 31/02366; H01L 31/02167; H01L 31/035227; H01L 31/0304; H01L 31/022475; H01L 31/0749; H01L 29/78678

(57) ABSTRACT

Architectures for tandem solar cell including two thin films forming a top layer and a bottom layer. Such cells can be bi-facial. Exemplary materials used for the top layer are CIGS (CGS), perovskites (Sn and Ge), amorphous silicon (a-Si), copper oxide, tin sulfide, CZTS and III-V materials. For the bottom layer an inorganic film such as either silicon or germanium may be used. In general, the architecture includes of a glass, plastic or metal substrate and a buffer layer, either an oxide insulator or nitride conductor.

This application claims priority to U.S. Provisional Patent Application No. 62/345,406 filed Jun. 3, 2016 entitled “Methods of Fabricating Solar Cells” and is hereby incorporated by reference in its entirety.

Solar cells are made of many different kinds of materials, and these materials require a device design that matches their particular qualities if they are to produce electricity from sunlight at their maximum potential. For a real device to approach the limiting efficiency, it should have an optimum energy gap, string light absorption, efficient charge separation and charge transport, and the load resistance should be optimized. Therefore, how a particular solar cell is designed is crucial to its performance and, even if the material engineered is ideal, if the overall device design is not adequate, the solar cell cannot perform well.

US patents and publications by P. Chaudhari and A. Chaudhari (2016/0293790; 2016/0260863; 2016/0322532; 2016/0329159; 2016/0329453; 2016/0322167; 2016/0322172; U.S. Pat. No. 9,349,995; U.S. Pat. No. 8,491,718; U.S. Pat. No. 9,054,249) all disclose methods for making tandem thin-film solar cells with high efficiency, high bandgap top layers or cells combined with a low bandgap bottom layer or cell, and employing a wide variety of materials. These patent applications are incorporated by reference in their entirety herein. In this present application, the architecture of solar cells, LEDS, and OLEDs for each of the materials covered in the applications is disclosed. The designs and architecture for each kind of solar cell are exemplified in various drawings with accompanying detailed descriptions. The variations herein are embodiments of the over-arching concept of two thin-films constituting a tandem solar cell semiconducting device.

### BACKGROUND OF THE INVENTION

A photovoltaic cell consists of a light absorbing material which is connected to an external circuit in an asymmetric manner. Charge carriers are generated in the material by the absorption of photons of light, and are driven towards one or the other of the contacts by the built-in-spatial asymmetry. This light driven charge separation establishes a photovoltage at open circuit, and generates a photocurrent at short circuit. When a load is connected to the external circuit, the cell produces both current and voltage and can do electrical work. To complete the photovoltaic conversion process, the excited electrons must be extracted and collected. This requires a mechanism for charge separation. Some intrinsic asymmetry is needed to drive the excited electrons away at their point of creation. (In general, charge separation involves positive holes/and or ions as well as electrons. We describe the process in terms of electrons for simplicity.) This can be provided by selective contacts such that carriers with a raised μ excited state are collected at one contact and those with a low μ ground state at the other. The difference in chemical potential between the contacts, delta μ, then provides a potential difference between the terminals of the cell. Once separated, the charges should be allowed to travel without loss to an external circuit and do the electrical work. For a current to be delivered, the material should be contacted in such a way that the promoted electrons experience a spatial asymmetry, which drives them away from the point of promotion. This can be an electric field, or a gradient in electron density. This asymmetry can be provided by preparing a junction at or beneath the surface. The junction may be an interface between two electronically different materials or between layers of the same material treated in different ways. It is normally large in area to maximize the amount of solar energy intercepted. For efficient photovoltaic conversion the junction quality is of central importance since electrons should lose as little as possible of their electrical potential energy while being pulled away. In practice preparing this large area junction successfully and without detriment to material quality is a challenge and limits the number of suitable materials. To conduct the charge to the external circuit the material should be a good electrical conductor. Perfect conduction means that carriers must not recombine with defects or impurities, and should not give up energy to the medium. There should be no resistive loss (no series resistance) or current leakage (parallel resistance). The material around the junction should be highly conducting and make good Ohmic contacts to the external circuit. Mechanisms for excitation, charge separation and transport can be provided by the semiconductor p-n junction, which is the classical model of a solar cell. In this system, charge separation is achieved by a charged junction between the layers of semiconductor of different electronic properties: i.e., the driving force which separates the charges is electrostatic.

There are several basic solar cell structures: p-n junction, p-i-n/n-i-p and multi-junction. A typical p-n junction structure includes a p-type doped layer and an n-type doped layer. Solar cells with a single p-n junction can be homo-junction or heterojunction solar cells. If both the p-doped layer and the n-doped layer are made of similar materials, with equal bandgaps, then the solar cell is called a homo-junction solar cell. In contrast, a heterojunction solar cell includes at least two layers of materials with different bandgaps. A p-i-n/n-i-p structure includes a p-type doped layer, an n-type doped layer, and an intrinsic (undoped) semiconductor layer (the i-layer) sandwiched between the p-layer and the n-layer. A multi junction structure includes multiple single-junction structures of different bandgaps stacked on top of one another. All these structures can be used in tandem solar cells and have been disclosed in prior art. What is needed, and disclosed for the first time herein, are architectures for thin-film tandem solar cells (as distinct from wafer based tandem cells) where the bottom thin-film is a crystalline material such as Si or Ge. Solar cell devices consisting of CSiTF (crystalline silicon thin-film) are presented here for the first time with various layers and configurations.

### SUMMARY OF THE INVENTION

The present invention provides various architectures for the over-arching concept of two thin-films constituting a tandem solar cell semiconducting device. The variations of this architecture disclosed in the present invention include: copper oxide/silicon thin film tandem solar cell; perovskite/silicon thin film tandem solar cell; a simple, textured perovskite solar cell; a tandem solar cell having a very high bandgap top layer with almost perfect lattice matching between layers; a tandem cell having a passivation layer; a perovskite-perovskite-silicon solar cell; a perovskite-perovskite-silicon tandem solar cell; a nanowire tandem solar cell; a multi junction solar cell configuration; a bottom gate transistor; an OLED device and a thin film tandem solar cell with CIGS (CGS).

### BRIEF DESCRIPTION OF THE DRAWINGS

Embodiments are illustrated by way of example, and not by way of limitation, in the figures of the accompanying drawings in which like reference numerals refer to similar elements and in which:

FIG. 1: shows the architecture of a copper oxide/silicon thin film tandem solar cell;

FIG. 2: shows the architecture of a perovskite/silicon thin film tandem solar cell using an insulator;

FIG. 3 shows the architecture of a simple, textured perovskite solar cell;

FIG. 4 shows the architecture of a tandem solar cell having a very high bandgap top layer with almost perfect lattice matching between layers;

FIG. 5 shows a tandem cell having a passivation layer;

FIG. 6: shows the architecture of a perovskite-perovskite solar cell;

FIG. 7 shows the architecture of another perovskite-perovskite silicon tandem solar cell according to the present invention;

FIG. 8 shows the structure for forming a nanowire tandem solar cell;

FIG. 9 shows the architecture of a multi junction solar cell configuration for the present invention;

FIG. 10 shows a bottom gate transistor;

FIG. 11 shows the structure of an OLED device; and

FIG. 12 shows a thin film tandem solar cell device architecture with CIGS/(CGS).

### DETAILED DESCRIPTION

The present application discloses architectures for tandem solar consisting of two thin films. Exemplary materials used for the top layer are CIGS (CGS), perovskites (Sn and Ge), amorphous silicon (a-Si), copper oxide, tin sulfide, CZTS and III-V materials. For the bottom layer an inorganic film such as either silicon or germanium may be used. In general, the architecture consists of a glass, plastic or metal substrate (for example, soda-lime or quartz), and a buffer layer, either an oxide insulator or nitride conductor. For electron selector layers (ESL) or hole transport layers (HTL), various materials can be used, such as tin oxide or Spiro-OMeTAD. Transparent conducting oxides (TCO) for top contacts can be indium tin oxide (ITO) or fluorine doped tin oxide (FTO), and the top contacts can be Ag or Au, for example. Various thicknesses of all these materials can be applied, and adjusted or modified according to desired results. However, the thickness of the absorber layers should be under 10 microns, wherein the top absorber layer may be under 1 micron and the bottom absorber layer should be 30 microns or less. The ESL and HTL are nanometers thick, typically 5 nm or less, and the buffer layers are at most 7 microns thick, and more likely to be 3 microns or less. The glass substrate can be several millimeters thick or less.

In the present invention, the terms ‘textured’ and ‘large grain’ have the following meaning: ‘textured’ means that the crystals in the film have preferential orientation either out-of-plane or in-plane or both. For example, in the present invention the films could be highly oriented out-of-plane, along the c-axis. By ‘large grain’ it is understood to imply a grain size larger than would have been achieved if a silicon (or other inorganic material) had been deposited under the same conditions but without metals. Moreover, ‘large grain’ means the grain size is comparable to or larger than the carrier diffusion length such that electron-hole recombination at grain boundaries is negligible. In semiconductor films this means that the grain size is greater than or equal to the film thickness.

In the present invention the term “bifacial” is defined as follows. Bifacial solar cells are solar cells in which both sides of the cell are transparent, allowing light to enter from both sides and thereby increasing photon conversion efficiency and power conversion efficiency (PCE). Such cells are usually made of glass on both sides, front and back, since glass is transparent. Bifacial solar cells not only capture the light falling on the front side of the solar panel, but also the light that reaches the rear side of the panel, such as light that is reflected from the background, from clouds, diffuse light, and even direct light at sunrise or sunset. Bifacial modules can therefore generate more energy as compared to traditional monofacial modules.

For thin-film solar cell devices the most efficient architecture is p+-i-n+, where i=intrinsic material. In the present disclosure, Al provides a p+ type silicon layer which acts as the hole transporter, on which the intrinsic perovskite film is deposited, followed by an n-type layer of some kind—there are several options. In this way, the Si layer acts both as a hole transporter and an absorber material at the same time.

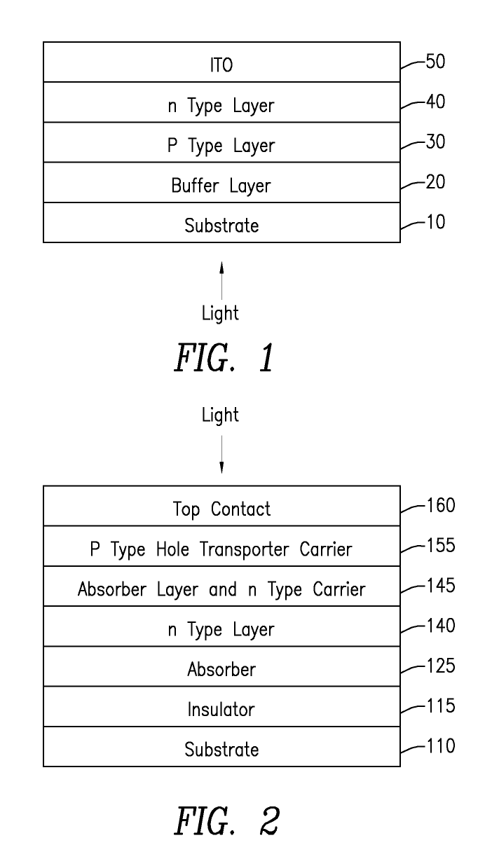

Another example of such a cell architecture is a copper oxide/silicon thin film tandem solar cell. As shown in FIG. 1, a buffer layer 20, MgO [111] for example, is deposited and/or formed on substrate 10 Substrate 10 is made of glass, soda-lime glass for example. A p-type layer 30. Cu₂O for example, is deposited on buffer layer 20. A n type layer 40, ZnO for example, is deposited on p type layer 30. ITO 50 is the top and final layer deposited on the n type layer to form a copper oxide/silicon thin film tandem solar cell. The light comes through substrate 10.

When designing a solar cell, a conducting layer as a bottom and top contact may be preferable. For example, TiN serves as a conductor. However, instead of a conducting oxide layer, an insulator as the bottom substrate may be advantageous—as has been proven with perovskites which in certain cases perform better with insulators such as Al₂O₃. Perovskite can act both as an absorber and a n-type component, transporting electronic charge out of the device, and it is possible to use an insulator as a scaffold as in the following structure (See FIG. 2).

FIG. 2 shows an example of a perovskite/silicon thin film tandem solar cell using an insulator. An insulator 115 is deposited and/or formed on substrate 110. Substrate 110 is made of soda-lime glass, for example. Insulator 115 is not an absorption layer nor is it a p or n type layer. Absorber layer 125, Si—Sn for example, is deposited on insulator 115. A n type layer 140, SnO₂ for example, is deposited on n type layer 140. A perovskite absorber layer and n type carrier 145 is deposited on n type layer 140. A p type hole transporter carrier 155, Spiro-OMeTAD for example, is deposited on the perovskite absorber layer 145. Finally, a top contact 160, Ag for example, is deposited on p type hole transporter carrier 155 for a perovskite/silicon thin film tandem solar cell.

By using an insulator, such as Al₂O₃ a perovskite layer can function as both an absorber layer and a n-type component, transporting electronic charge out of the device. In the present invention, instead of using Al₂O₃ as the insulator MgO may be used instead. Moreover, the MgO is textured. This insulator forces the perovskite to transport electronic charge out of the device. Thus, perovskites can behave as both p-type and n-type semiconductors. Such flexibility is crucial when designing thin-film tandem devices.

In another architecture, IV-VI SnS can be a p-type conductor and SnS₂ can be an n-type material. This is an advantage when designing the solar cell. Silicon doping of SnO₂ can improve the SnO₂ performance as an electron transport layer (ETL). In the device of FIG. 2, the hole (p-type carriers 155) are carried to the Spiro-OMeTAD, and electrons are carried through the SnO₂ layer. The holes from the silicon layer pass through the n type layer 140, SnO₂ layer for example, to the Spiro-OMeTAD layer 155.

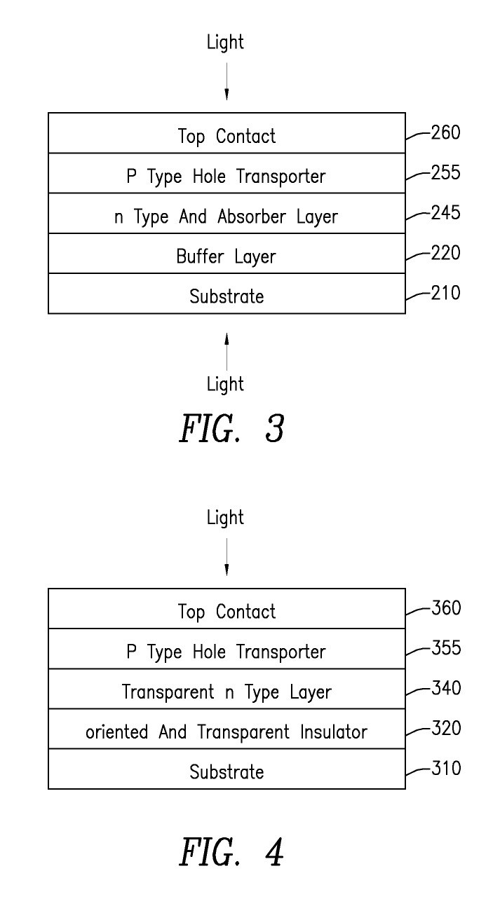

FIG. 3 shows the structure of a simple textured perovskite solar cell. A buffer layer 220, textured MgO [111] (cubic) for example, is deposited and/or formed on substrate 210. Substrate 210 is made of soda-lime glass, for example. A n-type absorber layer 245, a perovskite for example, is deposited on buffer layer 220. A p type hole transporter 255, for example Spiro-OMeTAD, is deposited on top of n type absorber layer 245. Finally, a top contact 260, for example Ag, is deposited on p type hole transporter carrier 255 for a simple, textured perovskite solar cell. Light comes into the solar cell from either direction. It is bi-facial.

In many of the devices addressed in the present invention, the metal thin-film that forms on the inorganic layer remains un-oxidized yet serves as a simple transparent conductor. Because the film thickness is in the regime of 10 nm, it is transparent. The thickness of the metal film can be controlled to optimize both transparency and conductivity. It should be noted that since the metal film is on silicon (not glass or plastic as is normally the case with TCOs) it can be even thinner without aggregating into droplets which happens on glass and plastic. The thin metal layer thus can serve as an effective electrode in a thin-film tandem device.

The more difficult solar cell architecture is the monolithically integrated cell, where the cell consists of a number of layers that are mechanically and electrically connected. These cells are difficult to produce because the electrical characteristics of each layer has to be carefully matched. In particular, the photocurrent generated in each layer needs to be matched, otherwise electrons will be absorbed between the layers. This limits their construction to certain materials, thought to be best met by III-V semiconductors. The current can be controlled by the absorber thicknesses of the tandem layers. The present invention facilitates this control greatly because the layers are deposited by various methods such as e-beam and the layers are thin-films, not wafers cut from a boule. Thus very thin films can be deposited, and fine-tuned to reach the exact thickness.

Recently, a CsSnI₃ perovskite was shown to function efficiently as a hole (p-type) conductor. Thus this fully inorganic perovskite would make an ideal perovskite top layer where the bottom layer is an n-type (doped) semiconductor such as Si.

It is possible to make an efficient perovskite solar cell without a hole transport layer so long as the perovskite film is pinhole free. Since CsSnI₃ is a hole conductor, no hole transport layer will be necessary.

In one embodiment, bromide is used instead of iodide since a higher bandgap 2.3 eV has been achieved using bromide with MAPb. The same may apply to MASn or CsSn. In this case, the material would be MASnBr₃.

FIG. 4 shows a tandem cell with a very high bandgap top and almost perfect lattice matching between layers. An oriented and transparent insulator 320 is deposited and/or formed on substrate 310. Substrate 310 is made of soda-lime glass, for example. Insulator 320 may be MgO [111], for example. A transparent n type layer 340, BaSnO₃ for example, is deposited on insulator 320. A p type hole transporter 355 is deposited on n type layer 340. Finally, a top contact 360, for example Ag, is deposited on p type hole transporter 355 for a tandem solar cell having a very high bandgap top layer and an almost perfect lattice.

BaSnO₃ has almost the same lattice constant as MgO—4.116 A and 4.212 A. Also, both are transparent. Since however BaSnO₃ has very high bandgap of 3.1 eV it may require doping for adjustment.

In the present invention, MgO is often used as an example of an oxide buffer layer. MgO has a passivation effect in perovskite solar cells. Passivation in the area of photovoltaics is the phenomenon whereby a thin oxide layer such as MgO or Al₂O₃ reduces surface recombination on a semiconductor film such as silicon or a perovskite. In photovoltaics, the absorption of a photon creates an electron-hole pair, which could potentially contribute to the current of the solar cell. Recombination in the area of photovoltaics is when the reverse process happens (according to the principle of detailed balance). That is, an electron and a hole meet and recombine, emitting a photon. Recombination is a significant loss mechanism in solar cells.

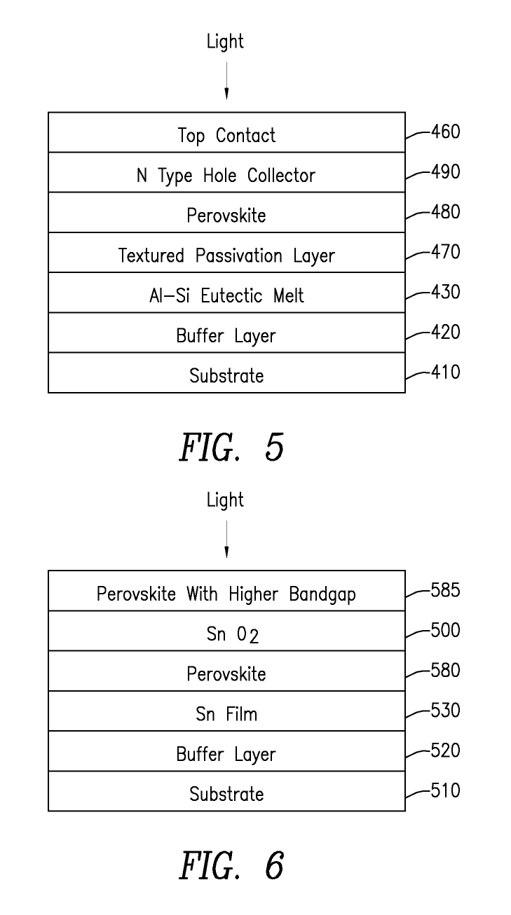

Instead of MgO, another ceramic such as Al₂O₃ can be used, creating another architecture with great potential. FIG. 5 shows the architecture of a tandem cell with a passivation layer. A buffer layer 420, MgO [111] (cubic) for example, is deposited and/or formed on substrate 410. Substrate 410 is made of soda-lime glass, for example. An Al—Si eutectic melt 430 is deposited on buffer layer 420. Eutectic melt 430 is p typed doped from Al. A textured passivation layer 470, a very thin film of Al₂O₃ for example, is deposited on eutectic melt 430. A perovskite, for example MASnBr₃, is deposited on top of passivation layer 470. N type hole collector 490, for example Spiro-OMeTAD, is deposited on perovskite layer 480. Finally, top contact 460, Ag for example, is deposited on n type hole collector 490 for a tandem cell having a passivation layer.

Performance of a tandem solar cell relies on the efficiency of charge transport layer at the interface between the two solar cell components. Moreover, research and development of two terminal monolithic tandem solar cell devices is extremely challenging because it requires compatibility of every processing step with all preceding layers and interfaces as well as precise optical and current matching between individual devices. The technology disclosed herein meets this challenge because both the top and bottom cells are thin-films and can be precisely controlled by the deposition technique, adjusting layer thickness down to the nanometer. Additionally, junction deterioration, a common problem due to high temperature processes, is avoided in the technology disclosed herein, all of which can take place at low temperature due to the use of eutectics. For example, in CIGS and CZTS bottom layer devices deterioration takes place at just 200° C. In the present technology, these materials are formed on top at low temperatures from the eutectic alloy metal and therefore deterioration is avoided.

Another type of solar cell architecture of the present invention can be seen in FIG. 6 which shows a Perovskite-Perovskite solar cell. A buffer layer 520, MgO film for example, is deposited and/or formed on substrate 510. Substrate 510 is made of glass. A Sn film 530 is deposited on buffer layer 520. Perovskite 580, MASnI₃ for example, is deposited on Sn film 530. SnO₂ 500, is deposited on top of perovskite layer 580. Finally, a perovskite layer 585, having a higher bandgap then perovskite layer 580, is deposited on SnO₂ 500 for a Perovskite-Perovskite Silicon solar cell. The bandgap is 1.8 eV.

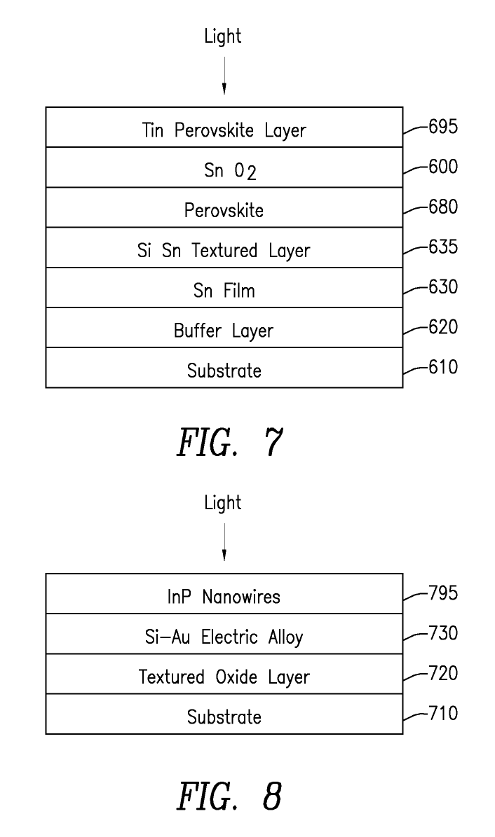

Another type of solar cell architecture of the present invention can be seen in FIG. 7 which shows a Perovskite-Perovskite Silicon tandem solar cell. A buffer layer 620, MgO film for example, is deposited and/or formed on substrate 610. Substrate 610 is made of glass. A Sn film 630 is deposited on buffer layer 620. A textured layer of SiSn 635 is deposited on the Sn film 630. Layer 635 has a bandgap of 1.1 eV. Perovskite layer 680, or example MASnI₃ having a bandgap of 1.3 eV, is deposited onto textured layer 635. SnO₂ 600, is deposited on top of perovskite layer 680. Finally, a high bandgap tin perovskite layer 695, for example FASnI₂ Br having a bandgap of 1.68 eV, is deposited on SnO₂ 600 for a Perovskite-Perovskite Silicon tandem solar cell.

Another type of solar cell is a Nanowire tandem solar cell. FIG. 8 shows a nanowire tandem cell according to the present invention. A textured oxide layer 720, MgO or TiN for example, is deposited and/or formed on substrate 710. Substrate 710 is made of soda-lime glass, for example. A Si—Au eutectic alloy 730 is deposited on oxide layer 720. InP nanowires 795 are formed from the Si—Au alloy.

Another tandem solar cell architecture has neither an HTL nor an ETL, or only one or the other. This has recently been referred as a “meso-superstructured solar cell” or MSSC. In this tandem architecture, a non-conducting oxide buffer layer is used for deposition of the semiconductor film. Examples of this oxide buffer layer are MgO and Al₂O₃, which are ceramics and non-conducting. They are also very stable and inert and therefore make for ideal buffers, or “scaffolds. In the technology of P. Chaudhari, they also influence the crystallographic orientation of the semiconductor film. For example, textured [111] MgO induces texture in the silicon film deposited on it, or the perovskite film for that matter. The non-conducting ceramics such as MgO and Al₂O₃ serve as insulators. Insulators play an important role in terms of improving the electrical properties of the semiconductor film deposited on them.

Multi junction solar cells can achieve even higher efficiency potentially than tandem (two layers or cells) designs. An example of a multi junction solar cell would be combining the invention of A. Chaudhari (U.S. Pat. No. 9,349,995 B2) involving a silicon/polymer hybrid solar cell, and depositing on this silicon layer an additional perovskite layer. The three layer device would constitute a multi junction solar cell.

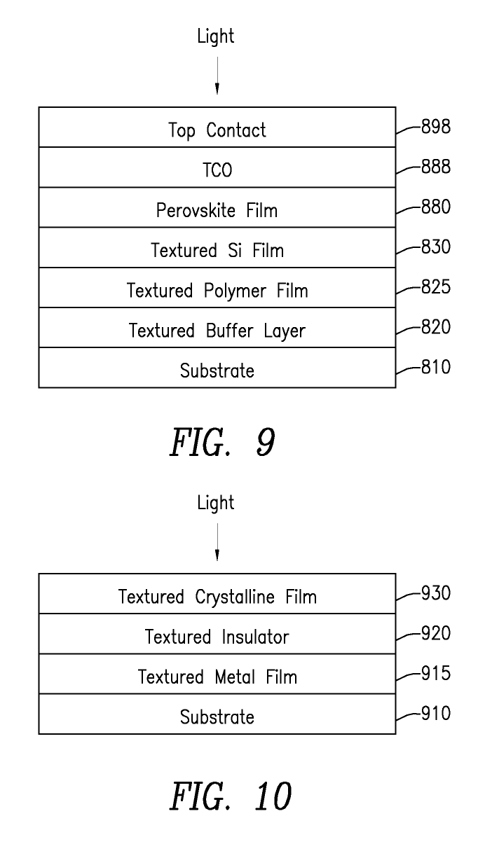

FIG. 9 shows the architecture of a multi junction solar cell based on the present invention. A textured oxide buffer layer 820 is deposited and/or formed on substrate 810. Substrate 810 is made of glass, for example. An textured polymer film 825 is deposited on buffer layer 820. A textured Si film 830 is deposited on polymer film 825. A perovskite film 880 is deposited on textured Si film 830. A TCO 888 is deposited on perovskite layer 880. Finally, a top contact layer 898 is deposited on TCO 888 for a multi junction solar cell configuration. Top contact layer 898 may consist of Ag or other metals.

A tandem cell can also be fabricated on a flexible glass substrate. FIG. 10 shows an exceptional example of such a device, a bottom gate transistor. A textured metal film 915, having a metal gate pattern for example, is deposited and/or formed on substrate 910. Substrate 910 is made of glass, for example. Textured insulator 920. MgO for example, is deposited on metal film 915. A textured crystalline silicon film or perovskite film 930 is deposited on insulator 920. The textured crystalline silicon film is from a eutectic.

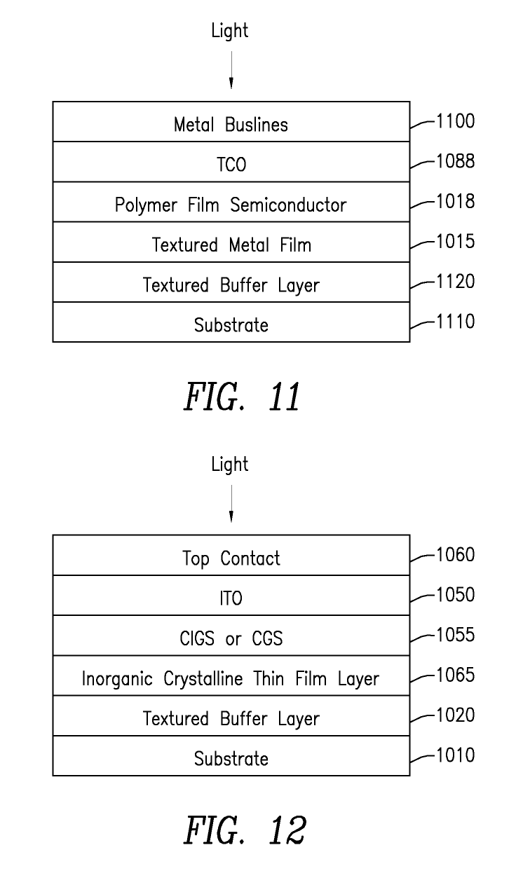

FIG. 11 shows the structure of an OLED device. A transparent textured oxide layer 1120, MgO for example, is deposited and/or formed on substrate 1110. Substrate 1110 may be made of glass or metal tape, for example. A textured metal film 1015 for a cathode is deposited on textured oxide layer 1120. A polymer film semiconductor 1018 is deposited on metal film 1015. A TCO 1088, for example ITO for anode, is deposited on polymer film 1018. Metal buslines 1100 are deposited on TCO 1088.

In one embodiment, a thin-film tandem device architecture with CIGS (CGS) can be developed. CIGS (CGS) is copper indium gallium selenide (or sulfur). FIG. 12 shows the structure of a CIGS (CGS) tandem solar device. A textured buffer layer 1020 is deposited on substrate 1010. Substrate 1010 may be made of glass or metal tape, for example. An inorganic crystalline thin film layer 1065 is deposited on buffer layer 1020. CIGS or CGS 1055 are deposited on the inorganic thin film 1065. ITO 1050 is deposited next. Finally, top contact layer 1060 is deposited on ITO 1050. For a higher bandgap CIGS material, CGS can be used instead. CGS has a bandgap equal to or greater than 1.5 eV. For the inorganic crystalline thin-film layer, silicon or germanium can be used. For the textured buffer layer, MgO can be used. All the layers in the device architecture based on these material are textured.

In another iteration of many of the architectures above, bi-facial solar cells are formed by allowing light to enter from both sides of the solar cell.

In the above examples a glass substrate is used, however the substrate can also be metal or plastic.

In the above examples, the higher bandgap top layer in the tandem solar cells absorbs higher energy photons and thus lowers the heat which would otherwise be created (instead of usable electricity) from the energy above the bandgap.

In the above examples, the layers are directly deposited onto the previous layer to form the solar cell. Intervening layers may be added if necessary.

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than a restrictive sense. Throughout this specification and the claims, unless the context requires otherwise, the word “deposit” and its variations, such as “deposited” and “depositing,” will be understood to imply the addition of the material. Any process of applying the material can be used, for example “forming,” and “nucleating” and not strictly construed as “deposited.” Furthermore, the indefinite article “a” or “an” is meant to indicate one or more of the item, element or step modified by the article.

What is claimed is:

1. A copper/oxide silicon thin film tandem solar cell comprising:
a substrate;
a buffer layer;
a p type layer;
an n type layer; and
an indium tin oxide layer.

2. A perovskite/silicon thin film tandem solar cell comprising:
a substrate layer;
an insulator;
an absorber layer;
a n type layer;
an absorber layer and n type carrier;
a p type hole transporter carrier; and
a top contact.

3. A simple textured perovskite solar cell comprising:
a substrate;
a buffer layer;
a n type absorber;
a p type hole transporter; and
a top contact.

4. The solar cell of claim 3 wherein the buffer layer is an oriented and transparent insulator.

5. A tandem solar cell comprising:
a substrate;
a buffer layer;
an Al—Si eutectic melt;
a textured passivation layer;
a perovskite;
a n type hole collector; and
a top contact.

6. A perovskite-perovskite-silicon tandem solar cell comprising:
a substrate;
a buffer layer;
a Sn film;
a first perovskite layer;
a layer of SnO₂; and
a second perovskite layer having a higher bandgap than the first perovskite layer.

7. The perovskite-perovskite-silicon tandem solar cell as recited in claim 6 further comprising a SiSn textured layer deposited after the Sn film and before the first perovskite layer, wherein the second perovskite layer includes tin.

8. A nanowire tandem solar cell comprising:
a substrate;
a textured oxide layer;
a Si—Au eutectic alloy; and
InP nanowires.

9. A multi junction solar cell comprising:
a substrate;
a textured buffer layer;
a textured polymer film;
a textured Si film;
a perovskite film;
a transparent conducting oxide; and
a top contact.

10. A bottom gate transistor comprising:
a substrate;
a textured metal film;
a textured insulator; and
a textured crystalline film.

11. An OLED device comprising:
a substrate;
a transparent textured oxide;
a textured metal film;
a polymer film semiconductor;
a transparent conducting oxide; and
metal buslines.

12. A CIGS/CGS thin film tandem solar cell device comprising:
a substrate;
a textured buffer layer;
an inorganic crystalline thin film layer;
a CIGS or CGS layer;
a ITO; and
a top contact.

13. The solar cell as recited in claim 1 wherein the buffer layer is MgO [111], the substrate is glass, the p type layer is Cu2O, and the n type layer is ZnO.

14. The solar cell as recited in claim 2 wherein the substrate is glass, the absorber layer is Si—Sn, the n type layer is SnO, the p type hole transporter carrier is Ometad-Spiro and the top contacting layer is Ag.

15. The solar cell as recited in claim 3 wherein the buffer layer is textured MgO, the substrate is glass, the n type absorber layer is a perovskite, the p type hole transporter is Spiro-Ometad and the top contact layer is Ag.

16. The solar cell as recited in claim 4 wherein the substrate is glass, the insulator is MgO [111], the transparent n type layer is BaSnO₃ and the top contact layer is Ag.

17. The solar cell as recited in claim 5 wherein the buffer layer is MgO [111], the substrate is glass, the eutectic melt is p typed from Al, the passivation layer is a very thin film of Al₂O₃, the perovskite is MASnBr₃, the n type hole collector is Spiro-Ometad and the top contact layer is Ag.

18. The solar cell as recited in claim 6 wherein the buffer layer is MgO, the substrate is glass, the perovskite is MASnI₃ and the bandgap of the second perovskite is 1.8 eV.

19. The solar cell as recited in claim 7 wherein the buffer layer is MgO, the substrate is glass, the perovskite layer is MASnI₃ and the tin perovskite layer is FASnI₂Br.

20. The solar cell as recited in claim 8, wherein the oxide layer is MgO or TiN and the substrate is glass.

21. The solar cell as recited in claim 9 wherein the substrate is glass and the top contact layer is Ag.

22. The bottom gate transistor as recited in claim 10 wherein the metal film has a metal gate pattern, the substrate is glass, the insulator is MgO and the crystalline silicon film is from a eutectic.

23. The OLED as recited in claim 11 wherein the textured transparent oxide layer is MgO and the substrate is glass or a metal tape.

24. The solar cell as recited in claim 12 wherein the CIGS or CGS layer has a bandgap equal to or greater than 1.5 eV.

25. The solar cell as recited in claim 3 wherein the cell is bifacial.
